(19) United States
(12) Patent Application Publication
(10) Pub. No.: US 2012/0068785 A1
(43) Pub. Date: Mar. 22, 2012

(54) SEMICONDUCTOR DEVICE

(75) Inventor: Toshiki Seshita, Kanagawa-ken (JP)

(73) Assignee: KABUSHIKI KAISHA TOSHIBA, Tokyo (JP)

(21) Appl. No.: 13/043,780

(22) Filed: Mar. 9, 2011

(30) Foreign Application Priority Data
Sep. 16, 2010 (JP) 2010-208299

(51) Int. Cl. H03K 17/687; H01P 1/15

(52) U.S. Cl. 333/103; 327/427

(57) ABSTRACT

According to one embodiment, a semiconductor device includes a body and a semiconductor element. The body includes a semiconductor mount, a first conductor and a second conductor provided on a periphery of the semiconductor mount. The semiconductor element is disposed on the semiconductor mount and includes a first through switching element, a first shunt switching element, a second through switching element, and a second shunt switching element. The first through switching element is connected between a common terminal and a first radio frequency terminal. A first radio frequency current is flowing through the first through switching element via the first conductor. The first shunt switching element is connected to the first radio frequency terminal. The second through switching element is connected between the common terminal and a second radio frequency terminal. The second shunt switching element has one terminal connected to the second radio frequency terminal and another terminal.

### CROSS-REFERENCE TO RELATED APPLICATIONS

This application is based upon and claims the benefit of priority from Japanese Patent Application No. 2010-208299, filed on Sep. 16, 2010; the entire contents of which are incorporated herein by reference.

### FIELD

Embodiments described herein relate generally to a semiconductor device.

### BACKGROUND

Semiconductor switches performing opening and closing of circuits can be used for various kinds of electronic devices. For example, in a radio frequency (RF) circuit section of a mobile phone, a transmitting circuit and a receiving circuit are selectively connected to a common antenna through a switch circuit for radio frequency signals.

Isolation is a one of important characteristic indices for a radio frequency switch. To increase the isolation, it is necessary to decrease a resistance of the shunt switching element at turned ON by enlarging a size of a shunt switching element. However, the size cannot be so large because a shunt switching element is generally laid out on a portion between pads from the aspect of layout efficiency.

In recent years, it is necessary to narrow a gap between pads because miniaturization of a radio frequency switch is strongly required. Therefore, it is necessary to minimize the size of the shunt switching element. However, a narrower gap between pads may cause to degrade isolation due to electromagnetic coupling between RF lines on a mounting board.

It is difficult to satisfy both of miniaturization and high isolation of a radio frequency switch.

### BRIEF DESCRIPTION OF THE DRAWINGS

FIG. 1 is a plan view illustrating the configuration of a semiconductor device according to a first embodiment;

FIG. 2 is an enlarged view of the semiconductor device shown in FIG. 1;

FIG. 3 is a circuit diagram illustrating the configuration of a radio frequency switch of the semiconductor device shown in FIG. 1;

FIG. 4 is a block diagram illustrating current paths of the semiconductor device;

FIG. 5 is an equivalent circuit diagram of the semiconductor device;

FIG. 6 is a characteristic graph illustrating simulation results of the isolation;

FIG. 7 is an enlarged plan view illustrating a semiconductor device according to a second embodiment;

FIG. 8 is an enlarged plan view illustrating a semiconductor device according to a third embodiment;

FIG. 9 is a circuit diagram illustrating the configuration of another radio frequency switch;

FIG. 10 is an enlarged plan view illustrating a semiconductor device according to a fourth embodiment;

FIG. 11 is a circuit diagram illustrating the configuration of a radio frequency switch of the semiconductor device shown in FIG. 10;

FIG. 12 is a circuit diagram illustrating the configuration of still another radio frequency switch; and

FIG. 13 is an enlarged plan view illustrating a semiconductor device of a comparative example.

### DETAILED DESCRIPTION

In general, according to one embodiment, a semiconductor device includes a body and a semiconductor element. The body includes a semiconductor mount, a first conductor and a second conductor. The first conductor and the second conductor are provided on a periphery of the semiconductor mount. The semiconductor element is disposed on the semiconductor mount. The semiconductor element includes a first through switching element, a first shunt switching element, a second through switching element, and a second shunt switching element. The first through switching element is connected between a common terminal and a first radio frequency terminal. A first radio frequency current is flowing through the first through switching element via the first conductor. The first shunt switching element is connected to the first radio frequency terminal. The second through switching element is connected between the common terminal and a second radio frequency terminal. The second shunt switching element has one terminal connected to the second radio frequency terminal and another terminal. An induction current induced in the second conductor by the first radio frequency current flows from the another terminal to the second shunt switching element.

Embodiments of the invention will now be described in detail with reference to the drawings. The drawings are schematic or conceptual; and the relationships between the thickness and width of portions, the proportions of sizes among portions, etc., are not necessarily the same as the actual values thereof. Further, the dimensions and proportions may be illustrated differently among the drawings, even for identical portions. In the specification and drawings, components similar to those described previously with reference to earlier figures are labeled with like reference numerals, and the detailed description thereof is omitted as appropriate.

### First Embodiment

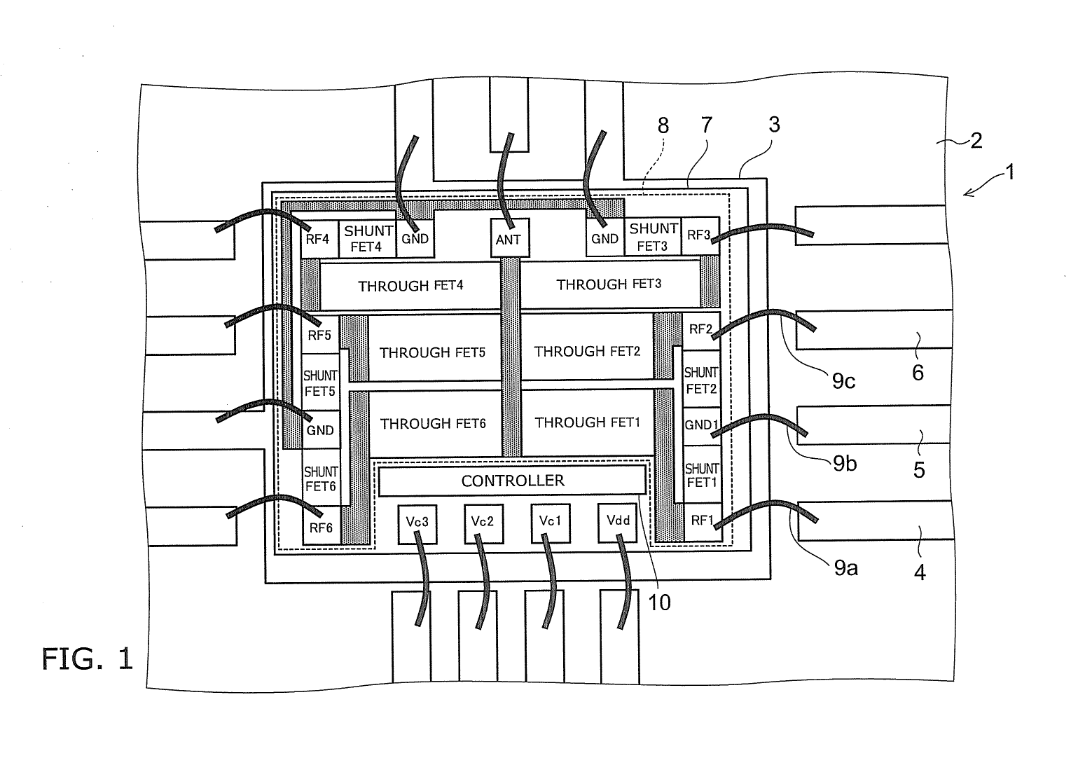

FIG. 1 is a plan view illustrating the configuration of a semiconductor device according to a first embodiment.

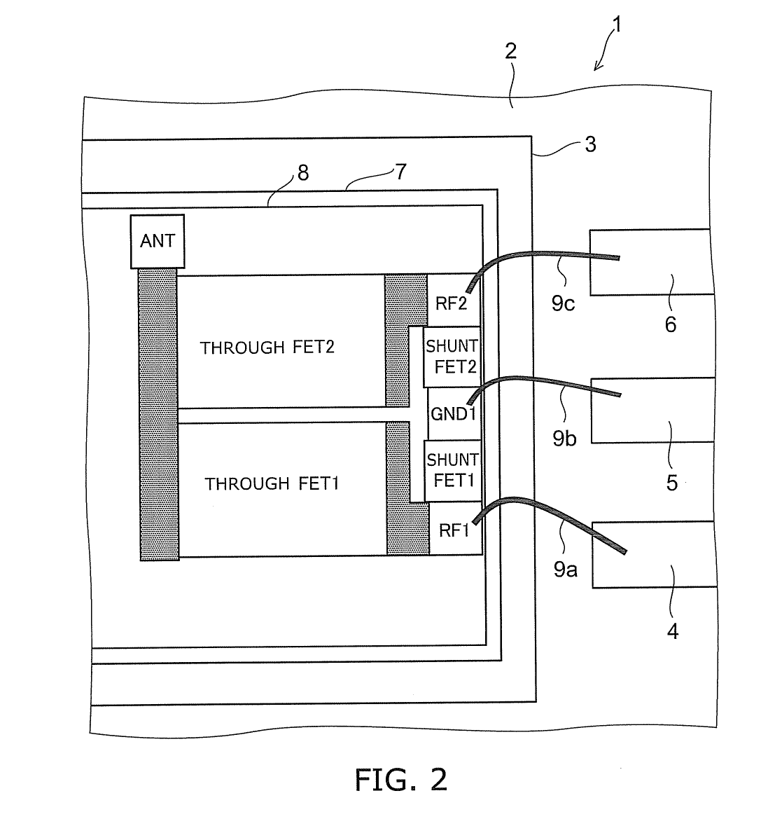

FIG. 2 is an enlarged view of the semiconductor device shown in FIG. 1.

As illustrated in FIG. 1 and FIG. 2, in the semiconductor device 1, a semiconductor mount 3 is provided near the center of a body 2. A plurality of conductors including a first conductor 5, a second conductor 6, and a third conductor 7 are provided on a periphery of the semiconductor mount 3. The first conductor 4, the second conductor 5, and the third conductor 6 are disposed to be parallel and close to each other.

A semiconductor element 7 is mounted on a semiconductor mount 3. The semiconductor element 7 includes a radio frequency switch 8 switching signal paths between a common terminal ANT and each of a plurality of radio frequency terminals RF1 to RF6 including a first radio frequency terminal RF1 and a second frequency terminal RF2.

Each of a through FET1 to a through FET6 is connected between the common terminal ANT and each of the radio frequency terminals RF1 to RF6, respectively. Each of a shunt FET1 to a shunt FET6 is connected to each of the radio frequency terminals RF1 to RF6, respectively.

The through FET3 to the through FET6, the shunt FET3 to the shunt FET6 and the radio frequency terminals RF1 to RF6 are omitted in FIG. 2.

The common terminal ANT and each of the radio frequency terminals RF1 to RF6 is electrically connected to the conductors of the body 2. The first radio frequency terminal RF1 and the second radio frequency terminal RF2 are connected to the first conductor 4 and the third conductors 6 by bonding wires 9a and 9c, respectively. A shunt terminal GND1 connected to the shunt FET1 and the shunt FET2, and the second conductor 5 are connected by a bonding wire 9b.

In the semiconductor device 1, surface mount of the semiconductor element 7 including the radio frequency switch 8 is performed on the body 2.

The body 2 is a mounting substrate, for example, a stacking structure in which a ground layer, a power supply layer, an interconnect layer, etc., are patterned and stacked via insulating layers. FIG. 1 shows a component side of a surface layer.

The semiconductor mount 3 is a ground pattern provided on the surface layer and is electrically connected to the common ground of the body 2. The semiconductor 3 is a region on which the semiconductor element 7 is mounted. The semiconductor mount 3 is applied with a ground potential and functions as a shield of the semiconductor element 7.

A plurality of conductors provided on the periphery of the semiconductor mount 3 are interconnects provided on the surface layer. Each of the conductors and a ground layer serve as a transmission line of a radio frequency signal, and the conductor supplies a power to the semiconductor element 7. The first conductor 4, the second conductor 5, and the third conductor 6 are close to the semiconductor mount 3 and close to each other in parallel. The first conductor 4, the second conductor 5, and the third conductor 6 are inductively coupled.

The first conductor 4, the second conductor 5, and the third conductor 6 are disposed in parallel in FIG. 2. However, the first conductor 4, the second conductor 5, and the third conductor 6 may be not in parallel but close to have inductive coupling, or may include a parallel portion.

The semiconductor element 7 is formed on, for example, an SOI (silicon on insulator) substrate. The radio frequency switch 8, a controller 10, a supply terminal Vdd, and switch signal terminals Vc1 to Vc3 are provided on the semiconductor element 7. Each of terminals is formed as pads.

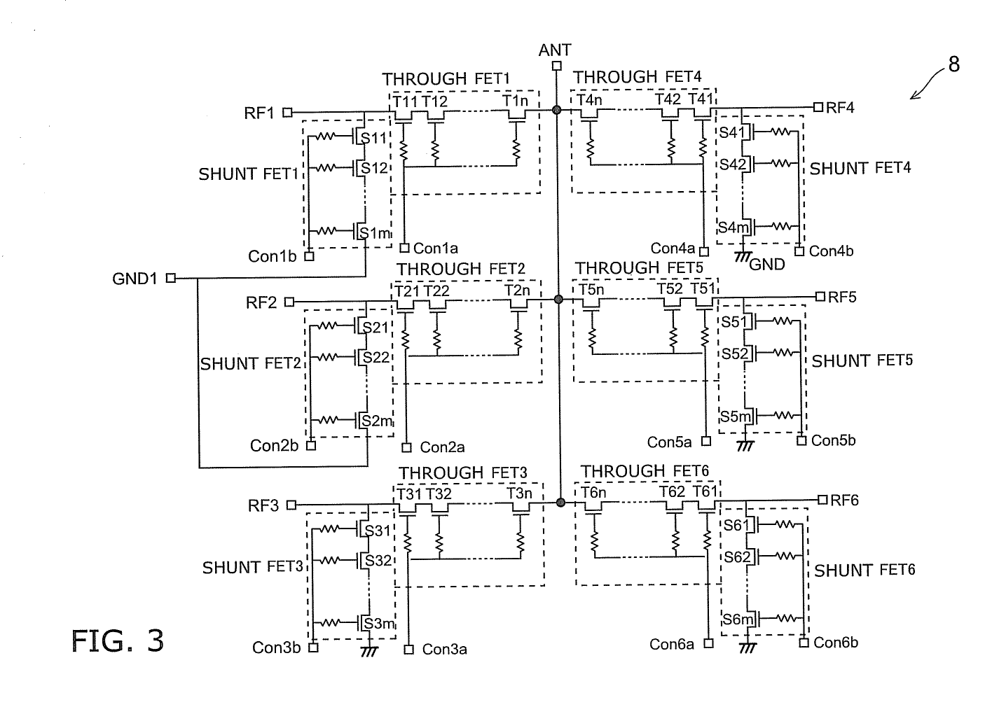

FIG. 3 is a circuit diagram illustrating the configuration of a radio frequency switch of the semiconductor device shown in FIG. 1.

As illustrated in FIG. 3, n stages (n being an natural number) of first through switching elements T11, T12, . . . , and T1n, and n stages of second through switching elements T21, T22, . . . , and T2n are connected in series between the common terminal ANT and each of the first and second radio frequency terminal RF1 and RF2, respectively. Further, n stages of through switching elements T31, T32, . . . , and T3n, T41, T42, . . . , and T4n, . . . ,T61, T62, . . . , and T6n are connected in series between the common terminal ANT and each of radio frequency terminals RF3 to RF6, respectively. Each of switching elements consists of a field effect transistor (FET).

The first through switching elements T11, T12, . . . , and Tin are connected between the common terminal ANT and the first radio frequency terminal RF1 as a through FET1. The second through switching elements T21, T22, . . . , and T2n are connected between the common terminal ANT and the second radio frequency terminal RF2 as a through FET2. The through switching elements T31, T32, . . . , and T3n are connected between the common terminal ANT and the radio frequency terminal RF3 as a through FET3. The through switching elements T41, T42, . . . , and T4n are connected between the common terminal ANT and the radio frequency terminal RF4 as a through FET4. The through switching elements T51, T52, . . . , and T5n are connected between the common terminal ANT and the radio frequency terminal RF5 as a through FET5. The through switching elements T61, T62, . . . , and T6n are connected between the common terminal ANT and the radio frequency terminal RF6 as a through FET6.

M stages (m being an natural number) of first shunt switching elements S11, S12, . . . , and S1m, and m stages of second shunt switching elements S21, S22, . . . , and S2m are connected in series between the shunt terminal GND1 and each of the first and second radio frequency terminal RF1 and RF2, respectively. Further, m stages of shunt switching elements S31, S32, . . . , and S3m, S41, S42, . . . , and S4m, . . . ,S61, S62, . . . , and S6m are connected in series between the ground and each of radio frequency terminals RF3 to RF6, respectively. Each of switching elements consists of a field effect transistor (FET).

The first shunt switching elements S11, S12, . . . , and S1m are connected between the shunt terminal GND1 and the first radio frequency terminal RF1 as a shunt FET1. The second shunt switching elements S21, S22, . . . , and S2m are connected between the shunt terminal GND1 and the second radio frequency terminal RF2 as a shunt FET2. The shunt switching elements S31, S32, . . . , and S3m are connected between the ground and the radio frequency terminal RF3 as a shunt FET3. The shunt switching elements S41, S42, . . . , and S4m are connected between the ground and the radio frequency terminal RF4 as a shunt FET4. The shunt switching elements S51, S52, . . . , and S5m are connected between the ground and the radio frequency terminal RF5 as a shunt FET5. The shunt switching elements S61, S62, . . . , and S6m are connected between the ground and the radio frequency terminal RF6 as a shunt FET6.

Each of gates of the first through switching elements T11, T12, . . . , and T1n connected to the first radio frequency terminal RF1 is connected to a control terminal Con1a via a resistor for prevention of high frequency leakage. Each of gates of the first shunt switching elements S11, S12, . . . , and S1m connected to the first radio frequency terminal RF1 is connected to a control terminal Con1b via a resistor for prevention of high frequency leakage.

Each of gates of the second through switching elements T21, T22, . . . , and T2n connected to the second radio frequency terminal RF2 is connected to a control terminal Conga via a resistor for prevention of high frequency leakage. Each of gates of the second shunt switching elements S21, S22, . . . , and S2m connected to the second radio frequency terminal RF2 is connected to a control terminal Con2b via a resistor for prevention of high frequency leakage.

Each of gates of the through switching elements T31, T32, . . . , and T3n connected to the radio frequency terminal RF3 is connected to a control terminal Con3a via a resistor for prevention of high frequency leakage. Each of gates of the shunt switching elements S31, S32, . . . , and S3m connected to the radio frequency terminal RF3 is connected to a control terminal Con3b via a resistor for prevention of high frequency leakage.

Each of gates of the through switching elements T41, T42, . . . , and T4n connected to the radio frequency terminal RF4 is connected to a control terminal Con4a via a resistor for prevention of high frequency leakage. Each of gates of the shunt switching elements S41, S42, . . . , and S4m connected to the radio frequency terminal RF4 is connected to a control terminal Con4b via a resistor for prevention of high frequency leakage.

Each of gates of the through switching elements T51, T52, . . . , and T5n connected to the radio frequency terminal RF5 is connected to a control terminal Con5a via a resistor for prevention of high frequency leakage. Each of gates of the shunt switching elements S51, S52, . . . , and S5m connected to the radio frequency terminal RF5 is connected to a control terminal Con5b via a resistor for prevention of high frequency leakage.

Each of gates of the through switching elements T61, T62, . . . , and T6n connected to the radio frequency terminal RF6 is connected to a control terminal Con6a via a resistor for prevention of high frequency leakage. Each of gates of the shunt switching elements S61, S62, . . . , and S6m connected to the radio frequency terminal RF6 is connected to a control terminal Con6b via a resistor for prevention of high frequency leakage.

The control terminals Con1a to Con6a and Con1b to Con6b are connected to the controller 10.

For example, to conduct between the first radio frequency terminal RF1 and the common terminal ANT, the n-stage first through switching elements T11 to T1n connected in series between the first radio frequency terminal RF1 and the common terminal ANT, namely the through FET1, are switched ON and the m-stage first shunt switching elements S11 to S1m connected in series between the first radio frequency terminal RF1 and the ground, namely the shunt FET1, are switched OFF. Simultaneously, it is sufficient that the second through switching elements connected between the second radio frequency terminal RF2 and the common terminal ANT and all of the other through switching elements between the radio frequency terminals RF3 to RF6 and the common terminal ANT are switched OFF; and the second shunt switching elements S21 to S2m connected between the second radio frequency terminal RF2 and the ground and all of the other shunt switching elements between the radio frequency terminals RF3 to RF6 and the ground are switched ON.

In other words, in the case recited above, an ON potential Von is applied to the control terminal Con1a; the ON potential Von is applied to the control terminals Con2b to Con6b; an OFF potential Voff is applied to the control terminal Con1b; and the OFF potential Voff is applied to the control terminals Conga to Con6a. The ON potential Von is a gate potential at which each of the FETs is switched to a conducting state and the ON resistance thereof has a sufficiently low value; and the OFF potential Voff is a gate potential at which each of the FETs is switched to an open state and the open state can be sufficiently maintained even when a radio frequency signal is superimposed. A threshold voltage Vth of each of the FETs is, for example, 0.1 V.

Control signals controlling the gate potential of each of the FETs of the radio frequency switch 8 are generated by the controller 10.

The controller 10 decodes terminal switch signals input from the switch signal terminals Vc1 to Vc3 and output the control signals to the radio frequency switch 8.

Isolation is a one of important characteristic indices for a radio frequency switch. Radio frequency signals leak out to OFF ports because an FET has a finite capacitance between the source and the drain even if open state. The isolation is the ratio of the input power to the leakage power.

A shunt switching element improves the isolation between the radio frequency terminal and the common terminal, when the through switching element having the radio frequency terminal connected to the shunt switching element is switched to open state. In other words, in the case where radio frequency signals leaks out to a radio frequency terminal connected to a through switching element switched to open state, the leakage radio frequency signals can flow to the ground through a shunt switching element switched to a conducting state.

To improve the isolation, it is necessary to decrease a resistance of the shunt switching element being turned on by enlarging a size of a shunt switching element. However, the size cannot be so large because a shunt switching element is generally laid out on a portion between pads from the aspect of layout efficiency. In the semiconductor device 1 as illustrated in FIG. 1, for example, the shunt FET1 to shunt FET6 are also disposed between pads of the semiconductor element 7.

To narrow a gap between pads for miniaturization, it is necessary to minimize the shunt switching element disposed between the pads. Further, the narrower gap between the pads may cause to degrade isolation due to electromagnetic coupling between RF lines on a mounting board.

As described above, it is difficult to satisfy both of miniaturization and high isolation of a radio frequency switch 8.

Therefore, in the semiconductor device 1, the shunt FET1 of the radio frequency switch 8 is connected between the first radio frequency terminal RF1 and the shunt terminal GND1. Further, the shunt FET2 is connected between the second radio frequency terminal RF2 and the shunt terminal GND1.

The radio frequency switch 8 is characterized by the circuit in which the source of each FET of the shunt FET1 and the shunt FET2 is connected to the shunt terminal GND1 and is not connected to the ground terminal GND inside the radio frequency switch 8.

Further, the semiconductor element 7 is characterized by the layout in which the shunt terminal GND1 is disposed between the first radio frequency terminal RF1 and the second radio frequency terminal RF2.

The first frequency terminal RF1 and the first conductor 4 are connected by the bonding wire 9a. The shunt terminal GND1 connected to shunt FET1 and the shunt FET2, and the second conductor 5 are connected by the bonding wire 9b. The second radio frequency terminal RF2 and the third conductor 6 are connected by the bonding wire 9c.

The first conductor 4 serves as a transmission line of the first radio frequency current flowing between the first radio frequency terminal RF1 and the common terminal ANT when the through FET1 is switched ON. The second conductor 5 serves as a transmission line of the current flowing through the shunt FET1 and the shunt FET2 via the shunt terminal GND1. The third conductor 6 serves as a transmission line of the second radio frequency current flowing between the second radio frequency terminal RF2 and the common terminal ANT when the through FET2 is switched ON.

Therefore, the first conductor 4, the second conductor 5, and the third conductor 6 are closely provided to the semiconductor mount 3, and are parallel and close to each other. The first conductor 4, the second conductor 5, and the third conductor 6 are inductively coupled. The second conductor 5 is connected to the common ground of the body 2 in a right region not illustrated in FIGS. 1 and 2.

The semiconductor device 1 is characterized by the mount in which the ground line dedicated for the shunt FET1 and the shunt FET2 is parallel disposed between the transmission lines of the first radio frequency current and the second radio frequency current.

For such configurations, the radio frequency power leaked from the first radio frequency terminal RF1 to the second radio frequency terminal RF2 can be reduced while conducting between the common terminal ANT and the first radio frequency terminal RF1. Further, the radio frequency power leaked from the second radio frequency terminal RF2 to the first radio frequency terminal RF1 can be reduced while conducting between the common terminal ANT and the second radio frequency terminal RF2. In other words, the isolation between pair of neighboring terminals can be improved.

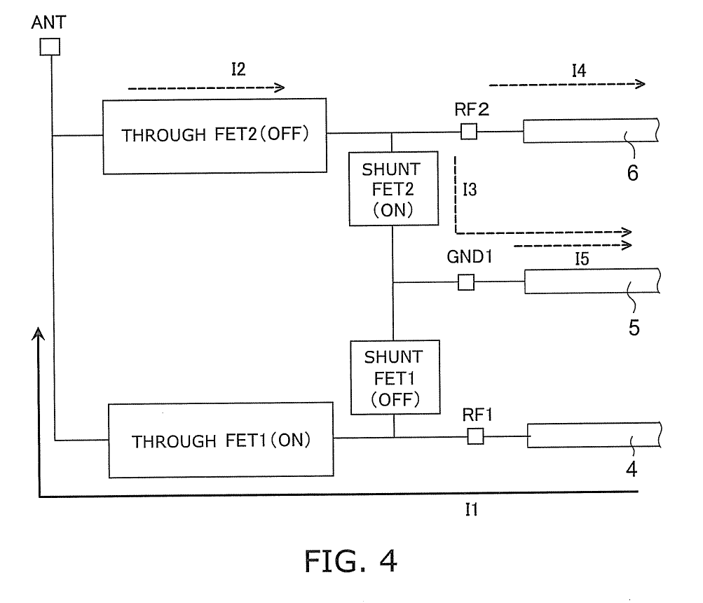

FIG. 4 is a block diagram illustrating current paths of the semiconductor device.

FIG. 4 conceptually illustrates the current paths in the case of conducting state between the common terminal ANT and the first radio frequency terminal RF1. An arrow shows a direction of the instantaneous current.

For example, when the through FET1 is switched ON, it is in the conducting state between the common terminal ANT and the first radio frequency terminal RF1.

The shunt FET1 connected between the first radio frequency terminal RF1 and the shunt terminal GND1 is switched OFF. The through FET2 connected between the common terminal ANT and the second radio frequency terminal RF2 is switched OFF. The shunt FET2 connected between the second radio frequency terminal RF2 and the shunt terminal GND1 is switched ON.

The radio frequency signal is input to the first radio frequency terminal RF1 via the first conductor 4. The radio frequency signal flows through the through FET1 being in an ON state and is output to the common terminal ANT. The current (first radio frequency current) flowing this path is taken as I1.

The current I2 flows through the through FET2 due to presence of its capacitance component, although the through FET2 is switched OFF. The current I2 is divided to current I3 flowing through the shunt FET2 being in an ON state and current I4 flowing through the third conductor 6 via the second radio frequency terminal RF2.

The current I4 flowing through the third conductor 6 is the leakage current.

The first conductor 4 and the second conductor 5 are parallel disposed and have mutual inductance. Therefore, induction current I5 is induced in the second conductor 5 by the first radio frequency current I1. The induction current I5 flows in the opposite direction to the first radio frequency current I1 as illustrated. Further, the induction current I5 is supplied from the shunt FET2. Therefore, the induction current I5 flows through the shunt FET2 in addition to the current I3.

The current I4 flowing through the third conductor 6 is reduced by the induction current I5 from the current I2 flowing through the through FET2. Therefore, the isolation between the first radio frequency terminal RF1 and the second radio frequency terminal RF2 can be improved.

The value of the induction current I5 may be adjusted by changing gaps, lengths, etc., between the first conductor 4, the second conductor 5, and the third conductor 6, and the isolation can be considerably improved.

The case where it is in the conductive state between the common terminal ANT and the second radio frequency terminal RF2 as the through FET2 switched ON is the same as described above.

As described above, in the semiconductor device 1, it is important that the shunt terminal GND1 of the radio frequency switch 8 is not connected to other ground terminal GND inside the semiconductor element 7. For example, if the shunt terminal GND1 were connected to other ground terminal GND, the induction current I5 would flow through not the shunt FET2 but the ground terminal GND connected to the shunt terminal GND1. Therefore, the leakage current I4 would not be reduced in this case.

To verify the improvement of the isolation, simulations of the isolation of the semiconductor device 1 were performed.

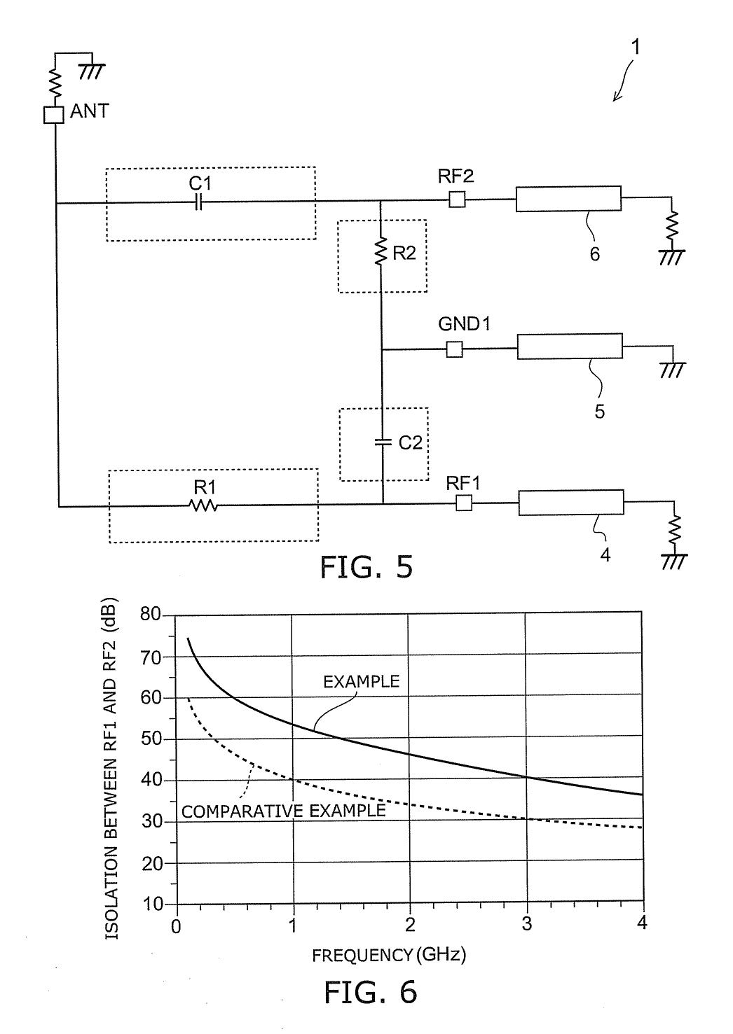

FIG. 5 is an equivalent circuit diagram of the semiconductor device.

FIG. 5 shows the equivalent circuit when it is in a conductive state between the common terminal ANT and the first radio frequency terminal RF1.

Resistors R1 and R2 denote the through FET1 and the shunt FET2 being in ON states, respectively. Capacitors C1 and C2 denote the through FET2 and shunt FET1 being in OFF states, respectively.

### Comparative Example

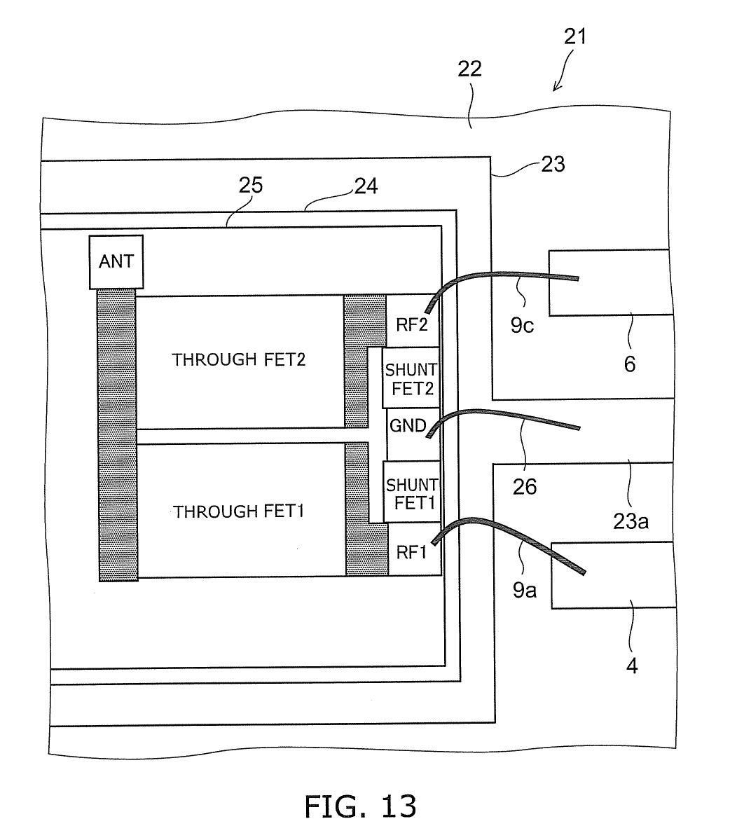

FIG. 13 is an enlarged plan view illustrating a semiconductor device of a comparative example.

As described in FIG. 13, in the semiconductor device 21 of the comparative example, a conductor 23a connected to a semiconductor mount 23 of a body 22 is disposed between a first conductor 4 and the third conductor 6.

Further, a radio frequency switch 25 is provided on a semiconductor element 24 mounted on the semiconductor mount 23. A shunt FET1 of the radio frequency switch 25 is connected between a first frequency terminal RF1 and a ground terminal GND. A shunt FET2 of the radio frequency switch 25 is connected between a second frequency terminal RF2 and the ground terminal GND.

Further, the first radio frequency terminal RF1 and the second radio frequency terminal RF2 are connected to the first conductor 4 and the third conductor 6 by bonding wires 9a and 9c, respectively. The ground terminal GND is connected to the conductor 23a by a bonding wire 26.

Therefore, the semiconductor device 21 of the comparative example is equivalent to a device that connects the shunt terminal GND1 of the equivalent circuit illustrated in FIG. 5 to the common ground.

Then, simulations are performed by using the equivalent circuit illustrated in FIG. 5. As a parameter of the radio frequency switch 8, the first conductor 4, the second conductor 5, and the third conductor 6, the following values are used, respectively.

R1=3.7 Ω, C1=0.1 pF;

R2=24 Ω, C2=0.017 pF;

the thickness from the surface layer to the ground plane=60 μm,

the metal thickness of the conductors=10 μm,

relative permittivity of the mounting board=4.7,

the width of the conductors=100 μm,

the gap between the conductors=50 μm,

the length of the conductors=2 mm.

FIG. 6 is a characteristic graph illustrating simulation results of the isolation.

FIG. 6 shows the frequency dependence of the isolation between the first radio frequency terminal RF1 and the second frequency terminal RF2, where the horizontal axis is taken as the frequency. The solid line illustrates the characteristics of the semiconductor device 1 according to the embodiment. The dashed line illustrates the characteristics of the semiconductor device 21 of the comparative example.

Although the isolation of the comparative example is 34 dB at the frequency of 2 GHz, the isolation of the semiconductor device 1 is 45.6 dB and improves by more than 10 dB.

Therefore, in the semiconductor device 1, the isolation between the first radio frequency terminal RF1 and the second radio frequency terminal RF2 is improved by configuring the mutual inductance among the first conductor 4, the second conductor 5, and the third conductor 6 to an appropriate value. At the same time, the sizes of the shunt FET1 and the shunt FET2 can be minimized to narrow the gap of the pads and to achieve the miniaturization. In the semiconductor device 1, the miniaturization and the improvement of the isolation can be compatible.

### Second Embodiment

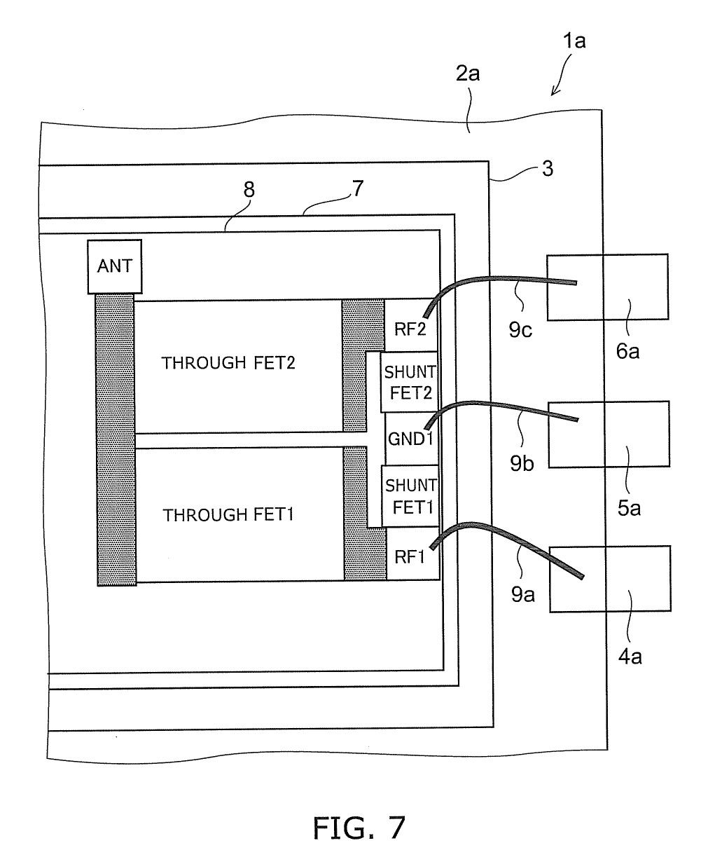

FIG. 7 is an enlarged plan view illustrating a semiconductor device according to a second embodiment.

As illustrated in FIG. 7, the semiconductor device la has a configuration in which a package is used as a body 2a and houses the semiconductor element 7 by, for example, sealing with resin, encapsulating with can, ceramic package, etc.

Further, the first conductor 4a, the second conductor 5a, and the third conductor 6a are leads of the body 2a, parallel disposed, and partly exposed from the body 2a.

The semiconductor element 7 on which the radio frequency switch 8 is provided and other components is the same as that of the semiconductor device 1 illustrated in FIG. 1.

In the semiconductor device la, the miniaturization and the improvement of the isolation can be compatible.

### Third Embodiment

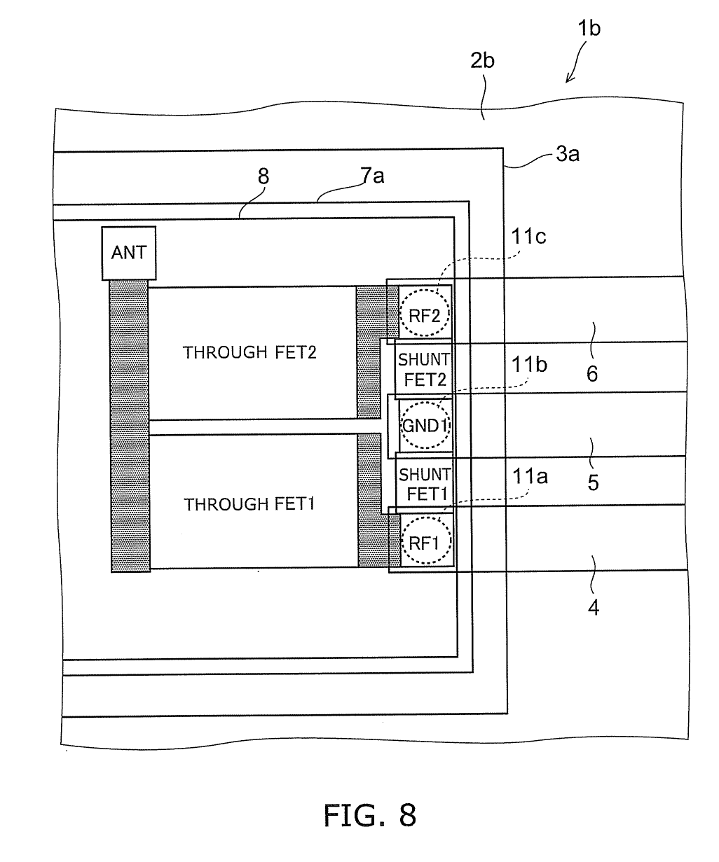

FIG. 8 is an enlarged plan view illustrating a semiconductor device according to a third embodiment.

As illustrated in FIG. 8, in the semiconductor device 1b, the semiconductor element 7a on which the radio frequency switch etc., are provided is mounted on the body 2b by bumps. In the semiconductor element 7a, bumps 11a, 11b, and 11c are provided on the first radio frequency terminal RF1, the shunt terminal GND1, and the second radio frequency terminal RF2, respectively. The first conductor 4, the second conductor 5, and the third conductor 6 are disposed inside the semiconductor mount 3a of the body 2b, and connected to the bumps 11a, 11b, and 11c, respectively.

The rest of the configuration, such as the radio frequency switch 8, is the same as the semiconductor device 1 illustrated in FIG. 1.

In the semiconductor device 1b, the miniaturization and the improvement of the isolation can be compatible. Further, more miniaturization is possible because of using no bonding wires.

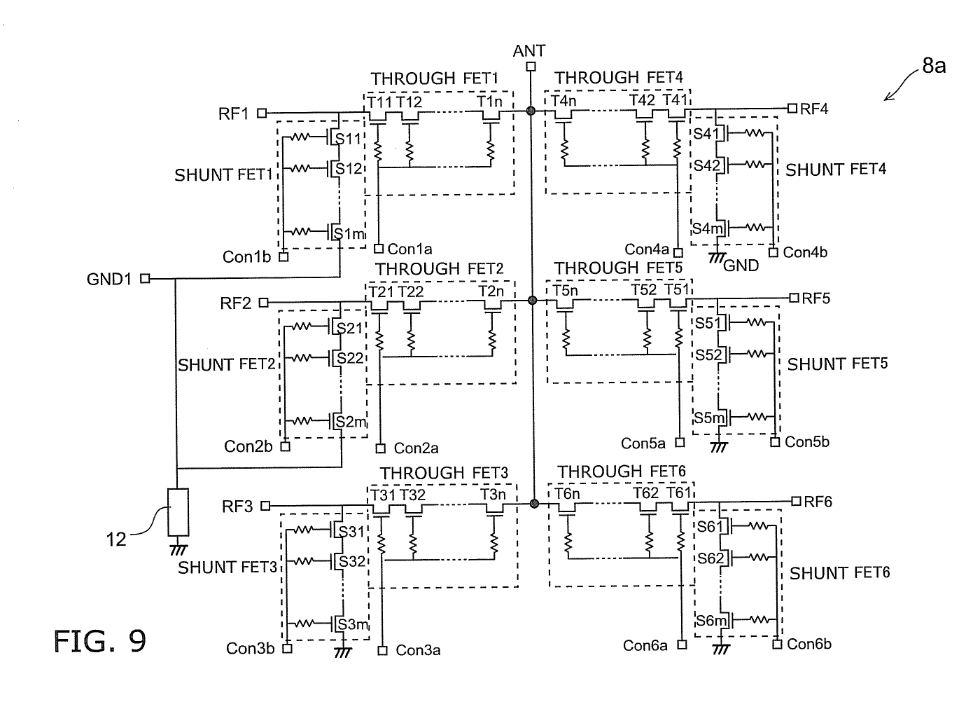

FIG. 9 is a circuit diagram illustrating the configuration of another radio frequency switch.

As illustrated in FIG. 9, in the radio frequency switch 8a, an ESD protection element 12 is provided between the shunt terminal GND1 and the ground terminal GND. The rest of the configuration is the same as the radio frequency switch 8 illustrated in FIG. 3.

The ESD tolerance between the shunt terminal GND1 and the ground terminal GND is improved by adding the ESD protection element 12. The ESD protection element 12 has sufficiently high impedance compared to the shunt FET1 and the shunt FET2 being in an ON state. Therefore, almost all the induction current I5 in FIG. 4 flow through the shunt FET1 or the shunt FET2.

The improvement of the isolation is not degraded to use the radio frequency switch 8. The miniaturization and the improvement of the isolation can also be compatible by using the radio frequency switch 8a in the semiconductor device 1, 1a, and 1b.

The ESD protection element 12 may be replaced with another type of an element, which has sufficiently high impedance compared to the shunt FET1 and the shunt FET2 being in an ON state and ESD tolerance.

### Fourth Embodiment

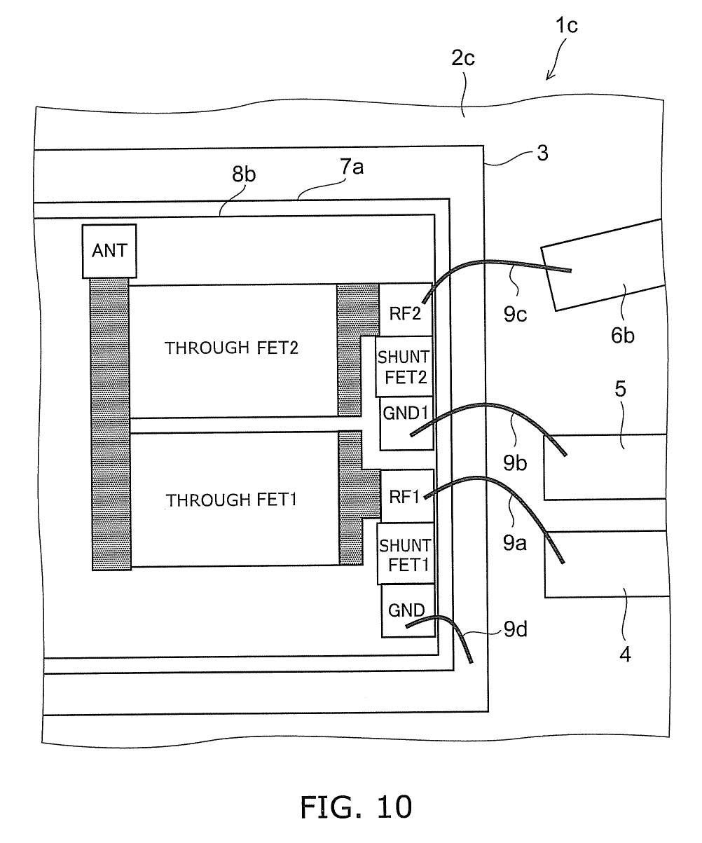

FIG. 10 is an enlarged plan view illustrating a semiconductor device according to a fourth embodiment.

As illustrated in FIG. 10, in the semiconductor device 1c, only a shunt terminal GND1 of a shunt FET2 is provided between a first radio frequency terminal RF1 and a second frequency terminal RF2.

The shunt FET1 is connected to the ground terminal GND and bonded to a semiconductor mount 3 of the body 2c by a bonding wire 9d. Further, a third conductor 6b is not disposed in parallel to a first conductor 4 and a second conductor 5. The rest of the configuration is the same as the semiconductor device 1 illustrated in FIGS. 1 and 2.

The first conductor 4 and the second conductor 5 are disposed in parallel in FIG. 10. However, the first conductor 4 and the second conductor 5 may be not in parallel but close to have inductive coupling, or may include a parallel portion.

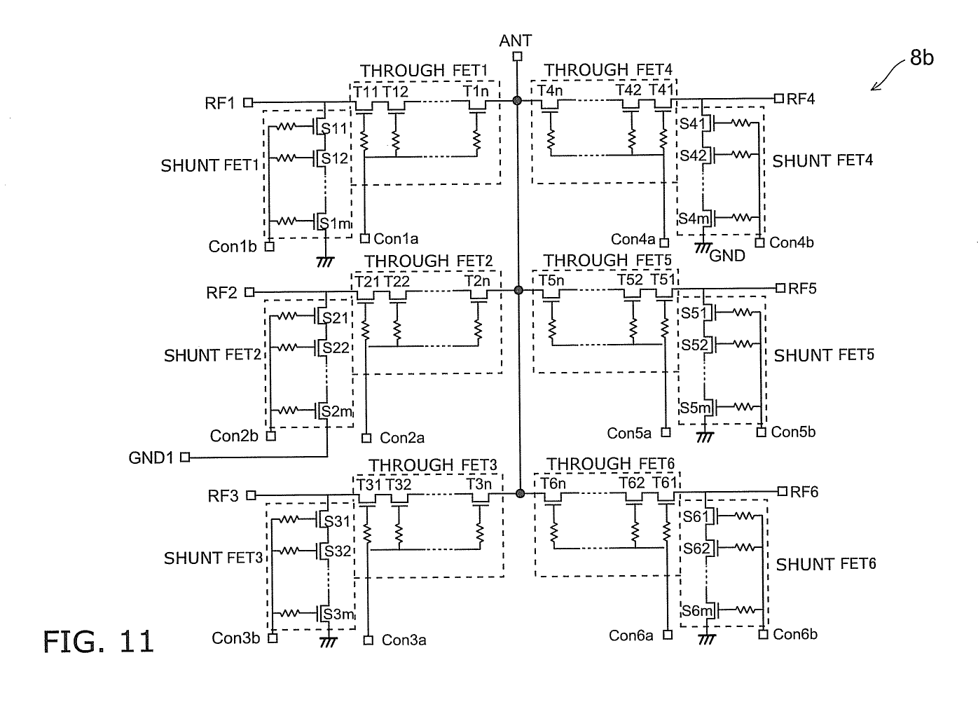

FIG. 11 is a circuit diagram illustrating the configuration of a radio frequency switch of the semiconductor device shown in FIG. 10.

As illustrated in FIG. 11, in the radio frequency switch 8b, only the source terminal of the shunt FET2 connected to the second radio frequency terminal RF2 is connected to the shunt terminal GND1.

The source terminal of the shunt FET1 connected to the first radio frequency terminal RF1 is similarly connected to the ground terminal as the other radio frequency terminals RF3 to RF6.

In the configuration, the isolation between the first radio frequency terminal RF1 and the second frequency terminal RF2 is improved only in the case where it is switched ON between the first radio frequency terminal RF1 and the common terminal ANT. On the other hand, in the case where it is switched ON between the second radio frequency terminal RF2 and the common terminal ANT, the isolation between the first radio frequency terminal RF1 and the second radio frequency terminal RF2 may not be improved.

However, as illustrated in FIG. 10, the gap of the first conductor 4 passing the first radio frequency current I1 and the second conductor 5 passing the induction current I5 of the shunt FET2 can be narrower. Further, the gap of the first conductor 4 and the third conductor 6 passing the leakage current I4 can be wider. Therefore, in the case where the first radio frequency terminal RF1 and the common terminal ANT is switched ON, the isolation between the first radio frequency terminal RF1 and the second radio frequency terminal RF2 can be more improved than the semiconductor device 1.

Although the reason why the first conductor 4 and the third conductor 6 are not disposed in parallel is to reduce the degradation due to the mutual inductance therebetween, they may be parallel if not necessary.

For example, in the case where the first radio frequency terminal RF1 is for transmission port and the second radio frequency terminal RF2 is for receiving port, the parallel configuration is highly effective.

When it is switched to a conducting state between the first radio frequency terminal RF1 and the common terminal ANT, i.e., the transmitting mode, power leaking to the receiving port must be sufficiently small.

However, the power input from the common terminal ANT at the receiving mode is feeble, and power leaking to OFF ports causes few problem.

FIG. 10 illustrates the configuration in which the semiconductor element 7a including the radio frequency switch 8b is bonded to the body 2c by bonding wires. However, as FIGS. 1A and 1B, a package mount and a bump mount can have the same effect.

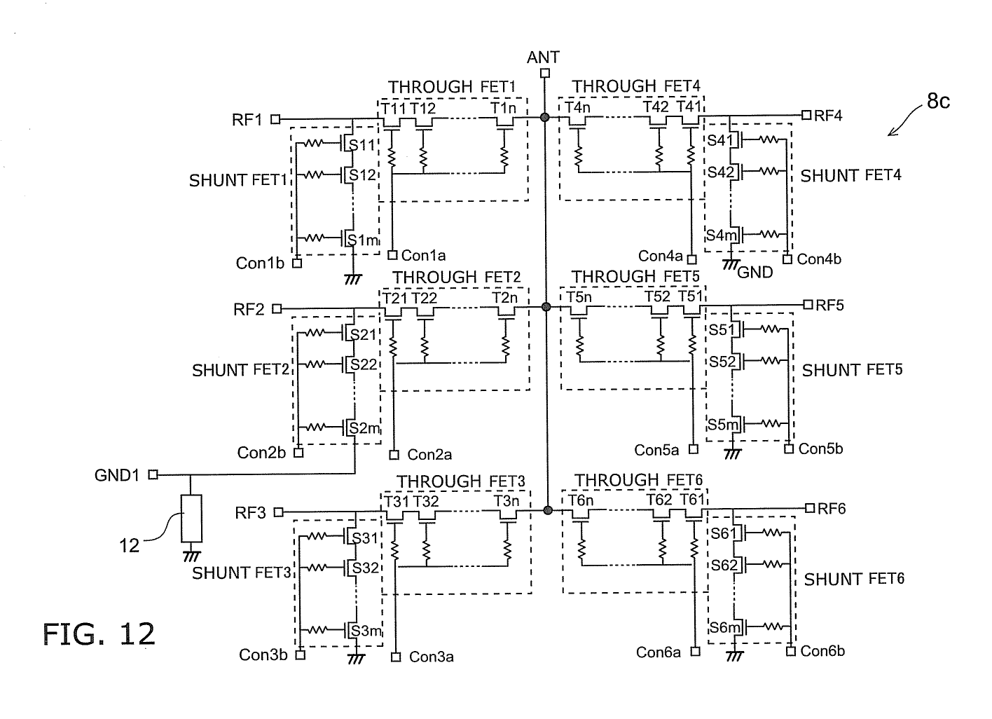

FIG. 12 is a circuit diagram illustrating the configuration of still another radio frequency switch.

As illustrated in FIG. 12, in the radio frequency switch 8c, an ESD element 12 is provided between a shunt terminal GND1 and a ground terminal GND.

The rest of the configuration is the same as the radio frequency switch 8b illustrated in FIG. 11.

The ESD tolerance between the shunt terminal GND1 and the ground terminal GND is improved by adding the ESD protection element 12. The ESD protection element 12 has sufficiently high impedance compared to the shunt FET2 being in an ON state. Therefore, almost all the induction current I5 in FIG. 4 flow through the shunt FET2.

The improvement of the isolation is not degraded to use the radio frequency switch 8c. The miniaturization and the improvement of the isolation can be compatible by using the radio frequency switch 8c in the semiconductor device 1c.

The ESD protection element 12 may be replaced with another type of an element, which has sufficiently high impedance compared to the shunt FET2 being in an ON state and ESD tolerance.

The case is described as an example in which the radio frequency switch 8 and 8a to 8c has a SP6T configuration in the semiconductor devices 1 and 1a to 1c, respectively. However, the radio frequency switch having another configuration, an mPnT (m-Pole n-Throw) configuration (m being a natural number and n being an integer not less than 2) may be similarly configured. Further, the isolation between radio frequency terminals equal to or more than 3 can be improved.

FETs constituting each of switching elements of radio frequency switches may be MOSFETs, HEMTs, MESFETs, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor device comprising:
a body including a semiconductor mount, a first conductor and a second conductor provided on a periphery of the semiconductor mount; and
a semiconductor element disposed on the semiconductor mount,
the semiconductor element including:
a first through switching element connected between a common terminal and a first radio frequency terminal,
a first radio frequency current flowing through the first through switching element via the first conductor;
a first shunt switching element connected to the first radio frequency terminal;
a second through switching element connected between the common terminal and a second radio frequency terminal; and
a second shunt switching element having one terminal connected to the second radio frequency terminal and another terminal, an induction current induced in the second conductor by the first radio frequency current flowing from the another terminal to the second shunt switching element.

2. The device according to claim 1, wherein the second shunt switching element is connected to the second conductor via a shunt terminal different from a ground terminal of the semiconductor element.

3. The device according to claim 1, wherein the second conductor is connected to a ground at a position separated from the semiconductor mount.

4. The device according to claim 1, wherein each of the first conductor and the second conductor is connected to the semiconductor element by a bonding wire.

5. The device according to claim 1, wherein each of the first conductor and the second conductor is connected to the semiconductor element by a bump.

6. The device according to claim 1, wherein the semiconductor element further includes an ESD protection element connected between the second shunt switching element and a ground terminal of the semiconductor element.

7. The device according to claim 1, wherein the first conductor and the second conductor are inductively coupled.

8. The device according to claim 1, wherein the first conductor and the second conductor include portions disposed to be parallel.

9. The device according to claim 1, wherein
the body further includes a third conductor disposed close to the first conductor and the second conductor, and
a second radio frequency current flows through the third conductor via the second terminal.

10. The device according to claim 9, wherein the first shunt switching element and the second shunt switching element are connected to the second conductor via a shunt terminal different from a ground terminal of the semiconductor element.

11. The device according to claim 9, wherein the second conductor is connected to a ground at a position separated from the semiconductor mount.

12. The device according to claim 9, wherein each of the first conductor, the second conductor, and the third conductor is connected to the semiconductor element by a bonding wire.

13. The device according to claim 9, wherein each of the first conductor, the second conductor, and third conductor is connected to the semiconductor element by a bump.

14. The device according to claim 9, wherein the semiconductor element further includes an ESD protection element connected among the first shunt switching element and the second shunt switching element, and a ground terminal of the semiconductor element.

15. The device according to claim 9, wherein the first conductor, the second conductor, and the third conductor are inductively coupled.

16. The device according to claim 9, wherein the third conductor is disposed to be parallel to the first conductor and the second conductor.

17. The device according to claim 9, wherein the first shunt switching element passes an induction current induced by the second radio frequency current to the second conductor.

18. The device according to claim 17, wherein the first shunt switching element and the second shunt switching element are connected to the second conductor via a shunt terminal different from a ground terminal of the semiconductor element.

19. The device according to claim 17, wherein the second conductor is connected to a ground at a position separated from the semiconductor mount.

20. The device according to claim 17, wherein the semiconductor element further includes an ESD protection element connected among the first shunt switching element and the second shunt switching element, and a ground terminal of the semiconductor element.
